(19) United States
(12) Patent Application Publication
(10) Pub. No.: US 2014/0167237 A1
(43) Pub. Date: Jun. 19, 2014

(54) POWER MODULE PACKAGE

(71) Applicant: SAMSUNG ELECTRO-MECHANICS CO., LTD., Suwon (KR)

(72) Inventors: Do Jae Yoo, Suwon (KR); Tae Hyun Kim, Suwon (KR); Kwang Soo Kim, Suwon (KR); Joon Seok Chae, Suwon (KR)

(73) Assignee: SAMSUNG ELECTRO-MECHANICS CO., LTD., Suwon (KR)

(21) Appl. No.: 13/950,205

(22) Filed: Jul. 24, 2013

(30) Foreign Application Priority Data
Dec. 14, 2012 (KR) 10-2012-0146345

(51) Int. Cl. H01L 23/495; H01L 23/48

(52) U.S. Cl. CPC H01L 23/495; H01L 23/48
USPC 257/676; 257/773

(57) ABSTRACT

Disclosed herein is a power module package, including: a substrate; semiconductor chips mounted on one surface of the substrate; external connection terminals connected to one surface of the substrate; and a connecting member having one end contacting the semiconductor chips and the other end contacting the external connection terminals and electrically and mechanically connecting between the semiconductor chips and the external connection terminals.

### CROSS REFERENCE TO RELATED APPLICATION

This application claims the benefit of Korean Patent Application No. 10-2012-0146345, filed on Dec. 14, 2012, entitled “Power Module Package”, which is hereby incorporated by reference in its entirety into this application.

### BACKGROUND OF THE INVENTION

1. Technical Field

The present invention relates to a power module package.

2. Description of the Related Art

Recently, as a power electronic industry is developed, an electronic product has been miniaturized and densified. Therefore, in addition to a method of decreasing a size of an electronic element itself, a method of installing elements and wires as many as possible in a predetermined space has become an important challenge in designing a power module package.

Meanwhile, a structure of a power module package according to the prior art has been disclosed in U.S. Pat. No. 5,920,119.

### SUMMARY OF THE INVENTION

The present invention has been made in an effort to provide a power module package capable of shortening a process time by simplifying a process of electrically connecting between an external connection terminal and a semiconductor chip and improving reliability by performing various bonding processes.

In addition, the present invention has been made in an effort to provide a power module package capable of easily performing process and mass-production due to a simple structure, and effectively radiating heat generated from the semiconductor chip.

According to a preferred embodiment of the present invention, there is provided a power module package, including: a substrate; semiconductor chips mounted on one surface of the substrate; external connection terminals connected to one surface of the substrate; and a connecting member having one end contacting the semiconductor chips and the other end contacting the external connection terminals and electrically and mechanically connecting between the semiconductor chips and the external connection terminals.

The external connection terminal may have one end and the other end, and the power module package may further include a fastening unit formed on one surface of the substrate and into which one end of the external connection terminal is insertedly fastened.

The power module package may further include a case formed on the substrate, covering one surface of the substrate and the semiconductor chip, and exposing the other end of the external connection terminal to the outside.

The power module package may further include a sealing member formed so as to enclose one surface of the substrate and the semiconductor in the case.

The semiconductor chip may be a power element.

The external connection terminal and the other end of the connecting member may integrally contact with each other.

The external connection terminal and the other end of the connecting member may separately contact from each other.

The other end of the connecting member may be provided with an insertion hole having a shape corresponding to a cross section in a thickness direction of the external connection terminal, the external connection terminal may have one end and the other end, and one end of the external connection terminal may penetrate through the insertion hole, such that the external connection terminal and the other end of the connecting member contact with each other.

The insertion hole may have a catching groove formed in an inner wall thereof, and a catching protrusion corresponding to the catching groove may be formed on an outer wall of a position corresponding to the insertion hole of the external connection terminal.

The power module package may further include a bonding member formed at a portion at which the external connection terminal and the insertion hole of the connecting member contact with each other.

The connecting member may be a lead frame.

According to another preferred embodiment of the present invention, there is provided a power module package, including: a substrate; semiconductor chips mounted on one surface of the substrate; external connection terminals connected to one surface of the substrate; and a connecting member having one end contacting the semiconductor chips and the other end integrally or separately contacting with or from the external connection terminals and electrically and mechanically connecting between the external connection terminals and the semiconductor chips.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a cross-sectional view showing a structure of a power module package according to a first preferred embodiment of the present invention;

FIG. 2 is a cross-sectional view showing a structure of a power module package according to a second preferred embodiment of the present invention; and

FIGS. 3 and 4 are cross-sectional views showing a fastening structure of an external connection terminal and a connecting member in the power module package according to the second preferred embodiment of the present invention.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

### First Preferred Embodiment

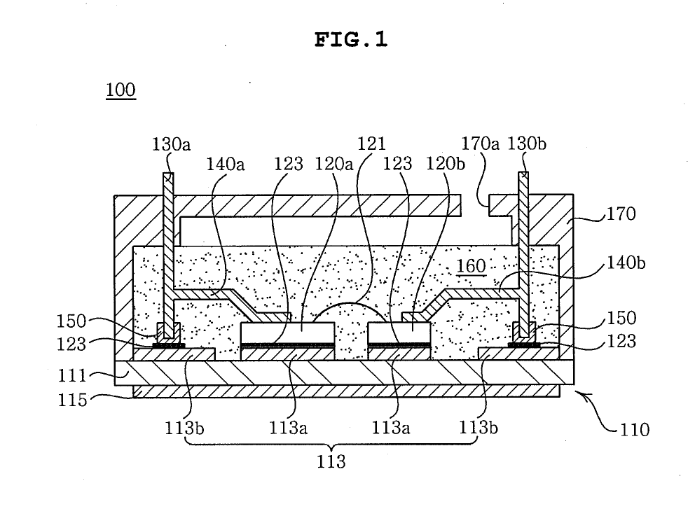

FIG. 1 is a cross-sectional view showing a structure of a power module package according to a first preferred embodiment of the present invention.

Referring to FIG. 1, the power module package 100 according to the first preferred embodiment of the present invention may include a substrate 110, semiconductor chips 120a and 120b mounted on one surface of the substrate 110, external connection terminals 130a and 130b connected to one surface of the substrate 110, and connecting members 140a and 140b having one end contacting the semiconductor chips 120a and 120b and the other end contacting the external connection terminals 130a and 130b and electrically and mechanically connecting between the semiconductor chips 120a and 120b and the external connection terminals 130a and 130b.

In the first preferred embodiment of the present invention, the substrate 110 may include an insulating material 111, a circuit layer 113 formed on one surface of the insulating material 111, and a metal layer 115 formed on the other surface of the insulating material 111.

In this case, the insulating material 111 may be a ceramic, but is not particularly limited thereto.

In the first preferred embodiment of the present invention, the substrate 110 has one surface and the other surface. In this case, one surface may mean a surface on which the semiconductor chips 120a and 120b are mounted based on FIG. 1, that is, on which the circuit layer 113 including a chip mounting pad 113a and an external connection pad 113b is formed, and the other surface may mean a surface opposite to one surface, that is, a surface on which the metal layer 115 is formed.

Although the first preferred embodiment of the present invention illustrates a direct bonded copper (DBC) substrate including the insulating material 111, the circuit layer 113, and the metal layer 115 as the substrate 110, as shown in FIG. 1, but is not particularly limited thereto. For example, a metal substrate having an anodized layer, a printed circuit board (PCB), a ceramic substrate, a substrate including a metal plate and an insulating layer circuit pattern, or the like may be used.

The external connection terminal 130a and 130b, which have a configuration electrically connecting between an external driving IC and the semiconductor chips 120a and 120b in order to drive the semiconductor chips 120a and 120b mounted on the substrate 110, may be formed in a pin form in the first preferred embodiment of the present invention as shown in FIG. 1, but are not particularly limited thereto.

In addition, the power module package 100 according to the first preferred embodiment of the present invention may further include fastening units 150 formed on one surface of the substrate 110 and into which one end of the external connection terminals 130a and 130b are insertedly fastened.

In this case, as shown in FIG. 1, a bonding layer 123 may be formed between the fastening unit 150 and the external connection member 113b. Here, the bonding layer 123 may be made of solder or conductive epoxy having relatively high thermal conductivity in order to effectively radiate heat, but is not particularly limited thereto.

In addition, the fastening unit 150 according to the first preferred embodiment of the present invention may be made of a conductive material, but is not particularly limited thereto.

In addition, the semiconductor chips 120a and 120b according to the first embodiment of the present invention may be a power element, where the power element may include a silicon controlled rectifier (SCR), a power transistor, an insulated gate bipolar transistor (IGBT), a metal oxide semiconductor (MOS) transistor, a power rectifier, a power regulator, an inverter, a converter, or a high power semiconductor chip or diode including a combination thereof.

According to the first preferred embodiment of the present invention, the bonding layer 123 may be formed between the semiconductor chips 120a and 120b and the chip mounting pad 113a, where the bonding layer 123 may be made of solder or conductive epoxy having relatively high thermal conductivity in order to effectively radiate heat, but is not particularly limited thereto.

The connecting members 140a and 140b according to the first preferred embodiment of the present invention serve to electrically and mechanically connect between the external connection terminals 130a and 130b and the semiconductor chips 120a and 120b and have one end and the other end, where the one end may contact the semiconductor chips 120a and 120b and the other end may contact the external connection terminals 130a and 130b.

In this case, the other ends of the connecting members 140a and 140b according to the first embodiment of the present invention may integrally contact the external connection terminals 130a and 130b.

That is, as shown in FIG. 1, the external connection terminals 130a and 130b having the pin form and the other ends of the connecting members 140a and 140b are integrally formed. As such, a structure in which the external connection terminals 130a and 130b and the connecting members 140a and 140b are integrally formed may be formed by an injection molding process using a mold having a shape corresponding to the structure, but is not particularly limited thereto.

In addition, one ends of the connecting members 140a and 140b according to the first embodiment of the present invention may be bonded to electrodes (not shown) of the semiconductor chips 120a and 120b. In this case, the bonding may be performed using the solder, an application of the conductive epoxy, or an ultrasonic bonding process, but is not particularly limited thereto.

As such, as the external connection terminals 130a and 130b and the connecting members 140a and 140b are integrally formed, the other ends of the connecting members 140a and 140b formed integrally with the external connection terminals 130a and 130b contact the electrodes (not shown) of the semiconductor chips 120a and 120b at the same time when the external connection terminals 130a and 130b are insertedly fastened into the fastening units 150 formed on the substrate 110, such that the fastening of the external connection terminals 130a and 130b and the connection between the external connection terminals 130a and 130b and the semiconductor chips 120a and 120b may be simultaneously performed.

As such, a separate wire bonding process electrically connecting between the external connection terminals 130a and 130b and the semiconductor chips 120a and 120b is not required, such that there is no clearance limitation with the wire bonding, the process is easy, and the process becomes simplified, thereby making it possible to shorten a total process time.

The connecting members 140a and 140b according to the first preferred embodiment of the present embodiment may be a lead frame, but are not particularly limited thereto.

As such, according to the first preferred embodiment of the present invention, the lead frame having an area wider than the wire is used as the connecting members 140a and 140b connecting the external connection terminals 130a and 130b to the semiconductor chips 120a and 120b, such that a portion bonding to the semiconductor chips 120a and 120b becomes wide, thereby making it possible to effectively radiate the heat generated from the semiconductor chips 120a and 120b. In addition, since various bonding processes such as ultrasonic bonding, soldering, and the like may be performed, a risk of a crack at a bonding interface is decreased, thereby making it possible to improve reliability of a product.

Meanwhile, although FIG. 1 shows a case in which the respective semiconductor chips 120a and 120b are connected by the wire 121, but is not particularly limited thereto. Also, the lead frame, a metal ribbon, or the like instead of the wire may be used.

In addition, the power module package 100 according to the first preferred embodiment of the present invention may further include a cover 170 formed on the substrate 110, covering one surface of the substrate 110 and the semiconductor chips 120a and 120b, and exposing the other ends of the external connection terminals 130a and 130b to the outside, as shown in FIG. 1.

In this case, the case 170 may be provided with an open portion 170a for injecting a molding material into the case 170.

Further, the power module package 100 according to the first preferred embodiment of the present invention may further include a sealing member 160 formed to enclose one surface of the substrate 110, the substrate chips 120a and 120b, the wire 121 electrically connecting between the semiconductor chips 120a and 120b, and the connecting members 140a and 140b electrically connecting between the semiconductor chips 120a and 120b and the external connection terminals 130a and 130b, in the case 170.

In this case, as the sealing member 160, silicone gel, epoxy molding compound (EMC), or the like may be used. However, the sealing member 160 is not particularly limited thereto.

In addition, although not shown, the power module package 100 according to the first preferred embodiment of the present invention may further include a heat sink bonded to the other surface of the substrate 110, that is, an exposed surface of the metal layer 115.

The heat sink includes a plurality of heat radiating pins in order to radiate the heat generated from the semiconductor chips 120a and 120b, in the air.

In addition, the heat sink is generally made of a copper (Cu) material or a tin (Sn) material or formed by coating the copper (Cu) material or the tin (Sn) material, but is not particularly limited thereto. The reason is that the copper (Cu) material or the tin (Sn) material excellently transfers heat and facilitates bonding between the heat sink and the substrate.

### Second Preferred Embodiment

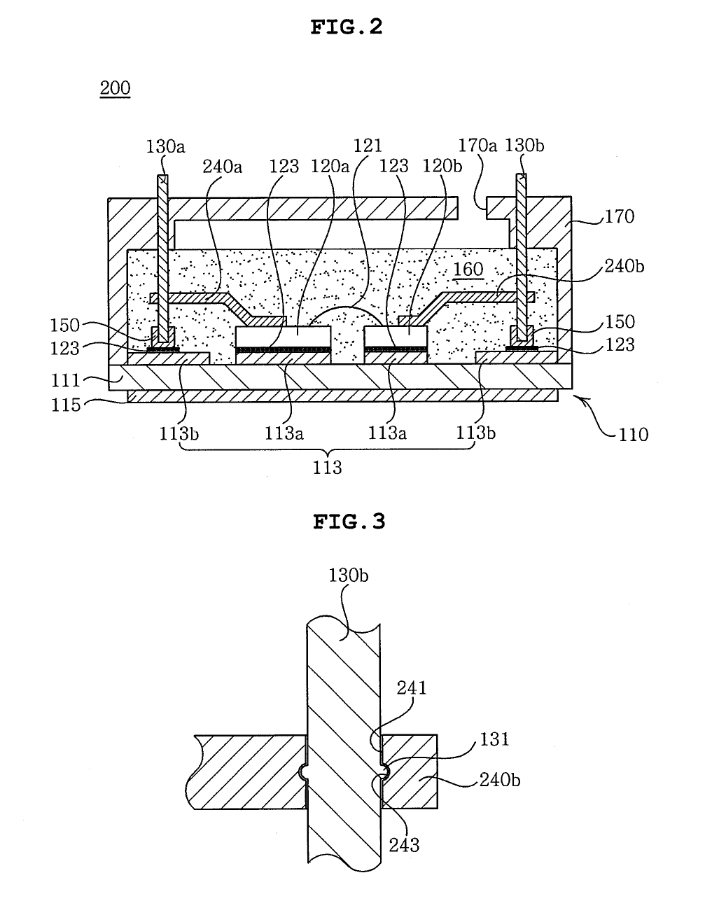

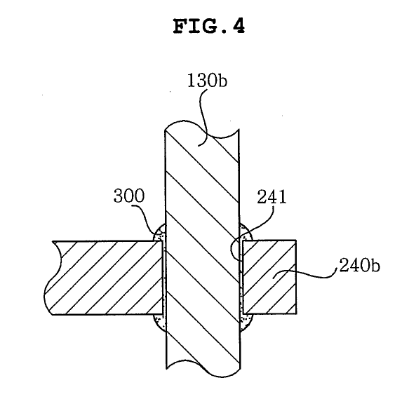

FIG. 2 is a cross-sectional view showing a structure of a power module package according to a second preferred embodiment of the present invention; and FIGS. 3 and 4 are cross-sectional views showing a bonding portion of an external connection terminal and a connecting member in the power module package according to the second preferred embodiment of the present invention. In the second preferred embodiment of the present invention, a description of components overlapped with the components described in the above-mentioned first preferred embodiment will be omitted. In addition, the same reference numerals will be used to describe the same components as the components described in the first preferred embodiment.

Referring to FIG. 2, the power module package 200 according to the second preferred embodiment of the present invention may include the substrate 110, the semiconductor chips 120a and 120b, the external connection terminals 130a and 130b, and connecting members 240 and 240b electrically and mechanically connecting between the external connection terminals 130a and 130b and the semiconductor chips 120a and 120b, similar to the power module package 100 the above-mentioned first preferred embodiment of the present invention.

The external connection terminals 130a and 130b and the connecting members 240a and 240b according to the second preferred embodiment of the present invention may be separately formed unlike the above-mentioned first preferred embodiment of the present invention.

That is, the external connection terminals 130a and 130b and the connecting members 240a and 240b are manufactured as separate configurations, respectively, and the manufactured external connection terminals 130a and 130b and connecting members 240a and 240b are then connected by a separate fastening process.

The external connection terminals 130a and 130b and the connecting members 240a and 240b according to the second preferred embodiment of the present invention may be connected to each other by forming an insertion hole 241 into which the external connection terminals 130a and 130b may be inserted at the other ends of the connecting members 240a and 240b and inserting the external connection terminals 130a and 130b into the insertion hole 241, as shown in FIGS. 3 and 4.

Specifically, the external connection terminals 130a and 130b and the connecting members 240a and 240b may be connected to each other by forming the insertion hole 241 having a shape corresponding to a cross section in a thickness direction of the external connection terminals 130a and 130b at the other ends of the connecting members 240a and 240b contacting the external connection terminals 130a and 130b and penetrating one end of the external connection terminals 130a and 130b through the formed insertion hole 241, as shown in FIG. 3.

In this case, an inner wall of the insertion hole 241 of the connecting members 240a and 240b may be provided with catching grooves 243 and an outer wall of a position corresponding to the insertion hole 241 in the external connection terminals 130a and 130b may be provided with catching protrusions 131 corresponding to the catching grooves 243.

Therefore, when one ends of the external connection terminals 130a and 130b are insertedly fastened into the fastening unit 150 by penetrating through the insertion hole 241 of the connecting members 240a and 240b, the catching protrusions 131 formed on the outer wall of the external connection terminals 130a and 130b are caught in the catching grooves 243 formed in the inner wall of the insertion groove 241 of the connecting members 240a and 240b, such that a connection portion between the external connection terminals 130a and 130b and the connecting members 240a and 240b may be fixed.

In this case, in order to make the connection portion between the external connection terminals 130a and 130b and the connecting members 240a and 240b more firm, the corresponding portion may be further provided with a bonding member (not shown).

Meanwhile, in the case in which the catching protrusions 131 and the catching grooves 243 are not formed at the external connection terminals 130a and 130b and the connecting members 240a and 240b, respectively, as described above, one ends of the external connection terminals 130a and 130b are insertedly fastened into the fastening unit 150 by penetrating through the insertion hole 241 of the connecting members 240a and 240b and the connection portion between the external connection terminals 130a and 130b and the insertion hole 241 of the connecting members 240a and 240b may be further provided with a bonding member 300 in order to reliably connect electrically and mechanically between the external connection terminals 130a and 130b and the insertion hole 241 of the connecting members 240a and 240b, as shown in FIG. 4.

In this case, the bonding member 300 may be formed using the solder, an application of the conductive epoxy, or an ultrasonic bonding process, but is not particularly limited thereto.

According to the preferred embodiment of the present invention, as the external connection terminals and the connecting member connecting between the external connection terminals and the semiconductor chips are integrally formed, a separate wire bonding process electrically connecting between the external connection terminals and the semiconductor chips is not required, such that there is no clearance limitation with the wire bonding and the process becomes simplified, thereby making it possible to shorten total process time.

In addition, according to the preferred embodiment of the present invention, a lead frame having a wider width than a wire is used as the connecting member connecting between the external connection terminals and the semiconductor chips, such that an area bonding to the semiconductor chips is increased, thereby making it possible to effectively radiate the heat generated from the semiconductor chips.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A power module package, comprising:
a substrate;
semiconductor chips mounted on one surface of the substrate;
external connection terminals connected to one surface of the substrate; and
a connecting member having one end contacting the semiconductor chips and the other end contacting the external connection terminals and electrically and mechanically connecting between the semiconductor chips and the external connection terminals.

2. The power module package as set forth in claim 1, wherein the external connection terminal has one end and the other end, and
the power module package further comprising a fastening unit formed on one surface of the substrate and into which one end of the external connection terminal is insertedly fastened.

3. The power module package as set forth in claim 2, further comprising a case formed on the substrate, covering one surface of the substrate and the semiconductor chip, and exposing the other end of the external connection terminal to the outside.

4. The power module package as set forth in claim 3, further comprising a sealing member formed so as to enclose one surface of the substrate and the semiconductor in the case.

5. The power module package as set forth in claim 1, the semiconductor chip is a power element.

6. The power module package as set forth in claim 1, wherein the external connection terminal and the other end of the connecting member integrally contact with each other.

7. The power module package as set forth in claim 1, wherein the external connection terminal and the other end of the connecting member separately contact from each other.

8. The power module package as set forth in claim 7, wherein the other end of the connecting member is provided with an insertion hole having a shape corresponding to a cross section in a thickness direction of the external connection terminal,
the external connection terminal has one end and the other end, and
one end of the external connection terminal penetrates through the insertion hole, such that the external connection terminal and the other end of the connecting member contact with each other.

9. The power module package as set forth in claim 8, wherein the insertion hole has a catching groove formed in an inner wall thereof, and
a catching protrusion corresponding to the catching groove is formed on an outer wall of a position corresponding to the insertion hole of the external connection terminal.

10. The power module package as set forth in claim 8, further comprising a bonding member formed at a portion at which the external connection terminal and the insertion hole of the connecting member contact with each other.

11. The power module package as set forth in claim 1, wherein the connecting member is a lead frame.

12. A power module package, comprising:
a substrate;
semiconductor chips mounted on one surface of the substrate;
external connection terminals connected to one surface of the substrate; and
a connecting member having one end contacting the semiconductor chips and the other end integrally or separately contacting with or from the external connection terminals and electrically and mechanically connecting between the external connection terminals and the semiconductor chips.
